(19) United States
(12) Patent Application Publication
(10) Pub. No.: US 2009/0242269 A1
(43) Pub. Date: Oct. 1, 2009

(54) PRINTED CIRCUIT BOARD, ELECTRONIC DEVICE AND CONNECTION DEVICE

(75) Inventor: Masashi Watanabe, Akishima-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Kabushiki Kaisha Toshiba, Tokyo (JP)

(21) Appl. No.: 12/345,535

(22) Filed: Dec. 29, 2008

(30) Foreign Application Priority Data
Mar. 27, 2008 (JP) 2008-083437

(51) Int. Cl. H05K 7/02

(52) U.S. Cl. 174/541

(57) ABSTRACT

According to one embodiment, a printed circuit board comprises a printed wiring board and a connection device mounted on the printed wiring board. The connection device comprises a main body, a casing enclosing the main body, a receiving section provided in the casing to receive a connector, and terminals extending through the main body and electrically connected to the connector in the receiving section. The main body includes a first portion extending into the receiving section in such a manner as to protect the tip portion of each terminal and a second portion arranged in a position corresponding to a proximal portion on the other end of the terminal with respect to the tip portion and fixed to the casing. The first portion is prepared independently of the second portion.

### CROSS-REFERENCE TO RELATED APPLICATIONS

This application is based upon and claims the benefit of priority from Japanese Patent Application No. 2008-083437, filed Mar. 27, 2008, the entire contents of which are incorporated herein by reference.

### BACKGROUND

1. Field

One embodiment of the invention relates to a printed circuit board comprising a connection device that establish connection with a connector, and an electronic device comprising such a printed circuit board, and the connection device.

2. Description of the Related Art

Jpn. Pat. Appln. KOKAI Publication No. 2007-179943 discloses a connection device for which the number of components is reduced and the assembly process is simplified. This connection device comprises a receptacle and a plug in which a plug contact and a shield casing are integrated in a contact holder. The receptacle includes a receiver contact holder, multiple receiver contacts, and a receiver shield casing. The receiver contact holder includes a block-shaped main body and a contact holding piece integrated with and protruding from the side surface of the main body. The plug includes the contact holder, the plug contact and the shield casing. A click member is arranged between the receptacle and the plug.

In this connection device, whether the plug is engaged in the receptacle at a predetermined position can be checked by way of the click member.

During the insertion of the plug into the receptacle, a force may be exerted on the plug in a direction diverted from an appropriate insertion direction. In a similar manner, the plug may be removed from the receptacle with a force exerted in a direction diverted from an appropriate removal direction. In both situations, a large bending stress may be imparted to the contact holding piece of the receptacle. If the receptacle is repeatedly subjected to the insertion and removal force in an inappropriate manner, the contact holding piece may be strained, or broken in the worst case.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to the first embodiment.

FIG. 2 is an exemplary perspective view of the printed circuit board of the portable computer in FIG. 1.

FIG. 3 is an exemplary sectional view of the connection device of the printed circuit board in FIG. 2 along a vertical direction of the connection device.

FIG. 4 is an exemplary perspective view of the main body and terminals of the connection device in FIG. 3.

FIG. 5 is an exemplary sectional view of the main body and terminals of the connection device in FIG. 4 along a horizontal direction.

FIG. 6 is an exemplary sectional view of a connection device of a portable computer according to the second embodiment along a vertical direction.

### DETAILED DESCRIPTION

Various embodiments according to the invention will be described hereinafter with reference to the accompanying drawings. In general, according to one embodiment of the invention, a printed circuit board comprises a printed wiring board and a connection device mounted on the printed wiring board. The connection device comprises a main body, a casing enclosing the main body, a receiving section provided in the casing to receive a connector, and terminals extending through the main body and electrically connected to the connector in the receiving section. The main body includes a first portion extending into the receiving section in such a manner as to protect the tip portion of each terminal and a second portion arranged in a position corresponding to a proximal portion on the other end of the terminal with respect to the tip portion and fixed to the casing. The first portion is prepared independently of the second portion.

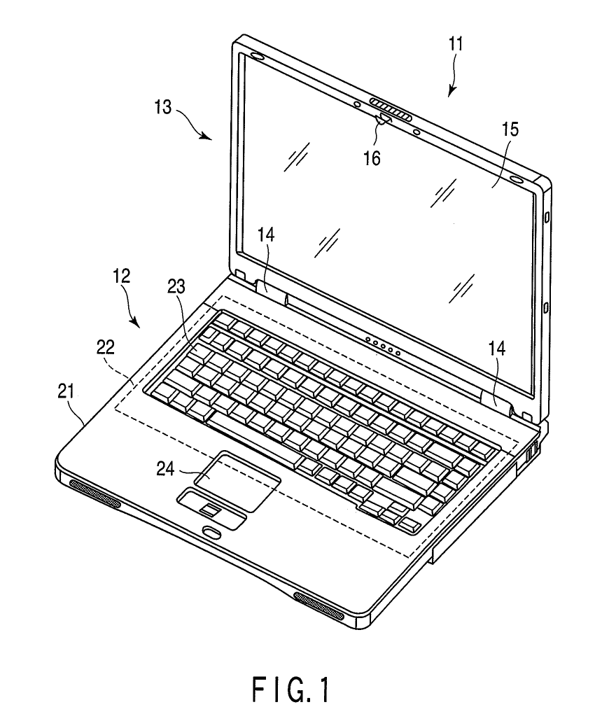

An electronic device according to the first embodiment will be explained below with reference to FIGS. 1 to 5. As illustrated in FIG. 1, a portable computer 11, which is an example of the electronic device, comprises a main unit 12, a display unit 13, and a hinge unit 14 arranged between the main unit 12 and the display unit 13. The hinge unit 14 rotatably supports the display unit 13 with respect to the main unit 12. The display unit 13 includes a liquid crystal display 15 and a latch 16.

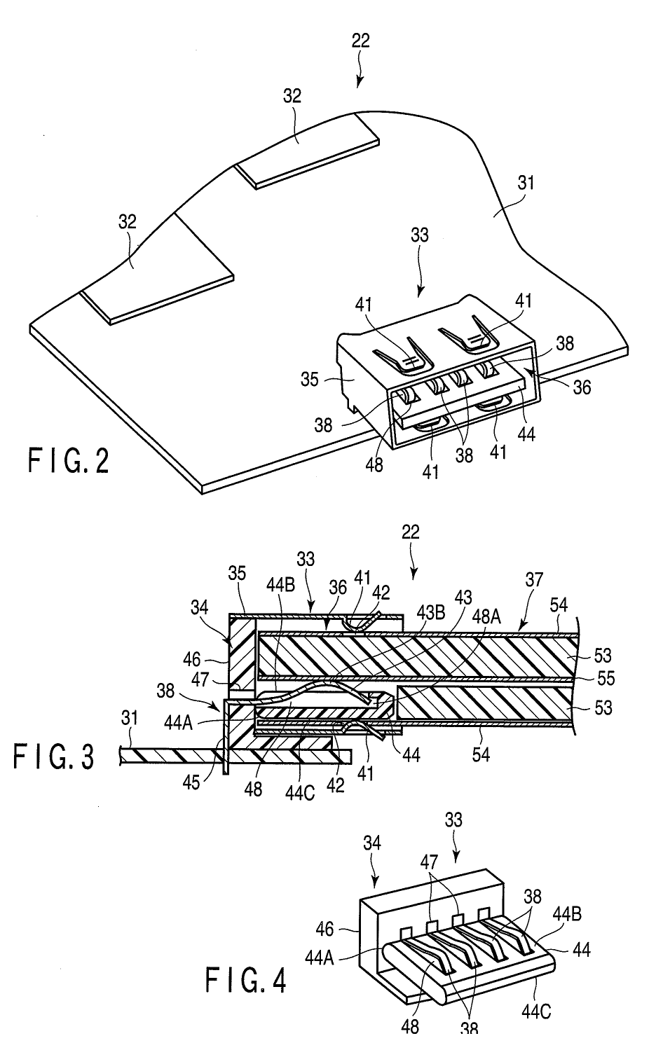

The main unit 12 includes a synthetic-resin housing 21, a printed circuit board 22 arranged in the housing 21, and a keyboard 23 and a touchpad 24 arranged on the housing 21. As illustrated in FIG. 2, the printed circuit board 22 comprises a printed wiring board 31 having a laminated structure of copper wiring layers, circuit components 32 mounted on the printed wiring board 31, and a connection device 33 also mounted on the printed wiring board 31.

The circuit component 32 may be a central processing unit (CPU), a graphics chip, a random access memory (RAM) and read only memory (ROM) of any type, or a north bridge.

As indicated in FIGS. 2 and 3, the connection device 33 may be constituted of a USB connector. The connection device 33 comprises a synthetic-resin main body 34, a casing 35 enclosing the main body 34, a receiving section 36 provided in the casing 35, and terminals 38 arranged in the receiving section 36 so as to establish an electrical connection with a connector 37. The casing 35 is formed of a metallic material and shaped into a box. The casing 35 is provided with claw-like click pieces 41 on its top and bottom surfaces. The click pieces 41 are fitted into an opening 42 of the connector 37 so as to prevent the connector 37 from being detached from the connection device 33.

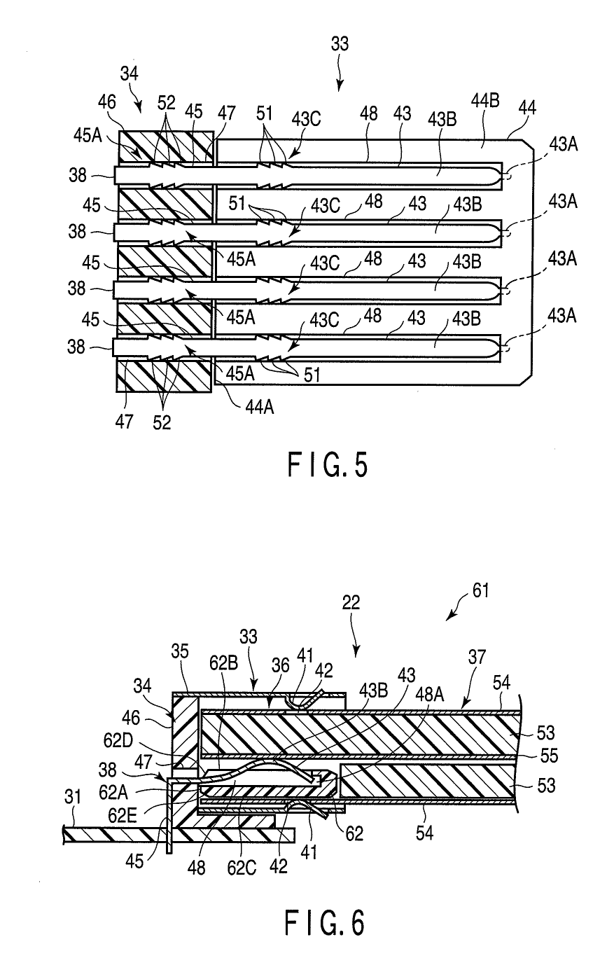

As illustrated in FIG. 3, the receiving section 36 is a space inside the casing 35 between the main body 34 and the casing 35, and a plug terminal 55 of the connector 37 is received into this space. As illustrated in FIGS. 3 and 4, the main body 34 includes a first portion 44 extending into the receiving section 36 so as to protect the tip portions 43 of the terminals 38, and a second portion 46 arranged in a position corresponding to the proximal portions 45 of the terminals 38 which are opposite to the tip portions 43. The second portion 46 is shaped into a block and fixed to the casing 35. As illustrated in FIG. 5, the second portion 46 is provided with four through-holes 47 through which the terminals 38 are guided.

As illustrated in FIGS. 3 and 5, the first portion 44 is formed to have a flat structure and covers, for example, one surface of each terminal 38 at its tip portion 43. The first portion 44 is prepared independently of the second portion 46 and is not connected to the second portion 46. The first portion 44 includes an end portion 44A opposing the second portion 46, a first surface 44B opposing the plug terminal 55 of the connector 37, and a second surface 44C on the other side of the first portion 44 with respect to the first surface 44B. The first portion 44 is provided with four grooves 48 recessed in the first surface 44B. The end portion 44A is semiround in cross section and positioned to touch the second portion 46. More specifically, the profile of the end portion 44A is a segment of circle arching toward the second portion 46 on the plane of the flat first portion 44 sectioned in its thickness direction.

The connection device 33 may be provided with four terminals 38. The terminals 38, which are also referred to as contacts, are formed of a metallic material and given flexibility. As illustrated in FIG. 3, the terminals 38 extend through the main body 34 and establish an electrical connection with the plug terminal 55 of the connector 37 in the receiving section 36.

As illustrated in FIGS. 3 and 5, each of the terminals 38 has an arching tip portion 43 and a proximal portion 45 on the other end. The tip portion 43 includes an insertion portion 43A having a reduced width, a contact portion 43B that is to be brought into contact with the plug terminal 55 of the connector 37, and the first engagement portion 43C engaged in the first portion 44. The insertion portion 43A is inserted into a sack portion 48A formed at the dead-end of each groove 48 on its tip side. The first engagement portion 43C is provided with three pairs of first claws 51 each protruding in, for example, V-shape in the width direction of the terminal 38. The first engagement portion 43C has a width approximately the same as, or slightly greater than, that of the groove 48. The first engagement portion 43C is therefore pushed into the groove 48 to be fixed to the first portion 44. In other words, the first portion 44 is supported by the terminals 38 at their first engagement portions 43C.

The proximal portions 45 has a second engagement portion 45A so as to be engaged in the second portion 46. The second engagement portion 45A is provided with three pairs of second claws 52 protruding in, for example, V-shape in the width direction of each terminal 38. The second engagement portion 45A has a width approximately the same as, or slightly greater than, that of each through-hole 47. The second engagement portion 45A is therefore pushed into the through-hole 47 to be fixed to the second portion 46.

As illustrated in FIG. 3, the connector 37 that is to be inserted is a plug comprising a molded body 53, a cover 54 surrounding the molded body 53, and a plug terminal 55 extending through the molded body 53. When the plug terminal 55 is inserted into the receiving section 36, an electrical connection is established with the terminals 38.

Under the condition of FIG. 3, if the user pulls the connector 37 in an upward direction or any other direction different from an appropriate insertion or removal direction, the first portion 44 smoothly moves upward together with the cover 54 of the connector 37 because the first portion 44 is arranged independently of the second portion 46. If the user pushes the connector 37 downward, the first portion 44 smoothly rotates and moves downward together with the cover 54 of the connector 37. Hence, according to the present embodiment, even when a force is applied onto the plug in a direction different from the insertion or removal direction, the first portion 44 is protected from load conditions.

When the connection device 33 according to the present embodiment is assembled, first, each terminal 38 is pushed into the corresponding through-hole 47 of the main body 34 so that the terminal 38 is guided through the through-hole 47. In this arrangement, the second engagement portion 45A of each terminal 38 is engaged in the inner surface of the through-hole 47. Thereafter, the terminal 38 is pushed into the corresponding groove 48 of the first portion 44 so that the terminal 38 is fitted into the groove 48. The first portion 44 is thereby fixed to the terminals 38. The first engagement portion 43C of each terminal 38 is engaged in the inside of the groove 48. Finally, the casing 35 is attached onto the main body 34, and thereby the connection device 33 is completed.

According to the first embodiment, the portable computer 11 comprises the housing 21 and the printed circuit board 22 housed in the housing 21. The printed circuit board 22 comprises the printed wiring board 31 and the connection device 33 mounted on the printed wiring board 31. The connection device 33 comprises the main body 34, the casing 35 enclosing the main body 34, the receiving section 36 provided in the casing 35 to receive a connector 37, and the terminals 38 extending through the main body 34 to establish an electrical connection with the connector 37 in the receiving section 36. The main body 34 includes the first portion 44 extending into the receiving section 36 so as to protect the tips of the terminals 38, and the second portion 46 formed in a position corresponding to the proximal portion 45 which is the other end of each terminal 38 and fixed to the casing 35. The first portion 44 is arranged independently of the second portion 46.

With such a structure, even if a force is applied to the connector device 33 in a direction different from an appropriate insertion or removal direction when the user inserts the connector 37 into the connection device 33 or removes the connector 37 from the connection device 33, the first portion 44 can freely rotate and move in accordance therewith. If a structure is such that the first portion 44 and the second portion 46 of the main body 34 are formed as a single unit, stress would be applied to the connecting point of the first portion 44 and the second portion 46. The structure of the present embodiment, however, is free from any strain or breakage of the first portion 44 caused in such a manner.

The first portion 44 is supported by the terminals 38. In general, terminals that establish a connection with a connector are formed to be flexible. In the above structure in which the first portion 44 is supported by the flexible terminals 38, the first portion 44 is elastically supported. This increases the degree of freedom in the rotational movement of the first portion 44.

The first portion 44 is given a flat structure having the end portion 44A opposing the second portion 46, the first surface 44B opposing the terminals 38 of the connector 37, and the second surface 44C provided on the other side of the first portion 44 with respect to the first surface 44B. The end portion 44A has a semiround cross section arching toward the second portion 46 on the profile plane of the first portion 44 in its thickness direction. In such a structure, no corners are positioned around the end portion 44A so that the second portion 46 is prevented from colliding with the corners when the first portion 44 rotates upward or downward. Furthermore, this semiround cross section smoothes the rotational movement of the first portion 44.

Now, a portable computer according to the second embodiment will be explained with reference to FIG. 6. A portable computer 61 is an example of the electronic device according to the second embodiment. The portable computer 61 is different from the first embodiment in the structure of a first portion 62 of the main body 34. The rest of the device structure is the same as the first embodiment. For this reason, the explanation focuses on the structure different from that of the first embodiment, while common components are given the same reference numbers and the explanation thereof is omitted.

The main body 34 according to the second embodiment includes the first portion 62 extending into the receiving section 36 so as to protect the tips of the terminals 38, and the second portion 46 corresponding to the proximal portions 45 provided on the other end of the terminals 38 with respect to the tip portions 43. The second portion 46 is formed into a block and fixed to the casing 35.

The first portion 62 is given a flat structure, formed independently of the second portion 46, and unfixed to the second portion 46. The first portion 62 includes an end surface 62A opposing the second portion 46, a first surface 62B opposing the plug terminal 55 of the connector 37, a second surface 62C provided on the side opposite to the first surface 62B, a first chamfered portion 62D positioned between the end surface 62A and the first surface 62B, and a second chamfered portion 62E positioned between the end surface 62A and the second surface 62C. The end surface 62A is brought into contact with the second portion 46.

The first chamfered portion 62D is literally a chamfered portion prepared by chamfering the edge formed by the end surface 62A and the first surface 62B. The first chamfered portion 62D is slanted with respect to the end surface 62A and the first surface 62B. Further, the second chamfered portion 62E is prepared by chamfering the edge formed by the end surface 62A and the second surface 62C. The first chamfered portion 62D is slanted with respect to the end surface 62A and the first surface 62B.

According to the second embodiment, the first portion 62 is formed into a flat structure, including the end surface 62A touching the second portion 46, the first surface 62B opposing the connector 37, the second surface 62C provided on the other side of the first portion 62 with respect to the first surface 62B, the first chamfered portion 62D prepared by chamfering the edge formed by the end surface 62A and the first surface 62B, and the second chamfered portion 62E prepared by chamfering the edge formed by the end surface 62A and the second surface 62C.

According to this embodiment, the first portion 62 and the second portion 46 are not fixed to each other, and thus a strain and breakage of the connected portion of the first portion 62 and the second portion 46 can be avoided. Moreover, when the first portion 62 moves upward or downward, a collision of a corner of the first portion 62 with the second portion 46 can be avoided. The rotational movement of the first portion 62 can be thereby smoothed.

The electronic device according to the present invention is not limited to the portable computers 11 and 61. The present invention may be applied to any other types of electronic devices such as a personal digital assistant. The invention may be modified in various manners without departing from the scope of the invention. The connection device is not limited to a USB connector, but may be applied to any IEEE 1394 device and High-Definition Multimedia Interface (HDMI).

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed circuit board, comprising:
a printed wiring board; and
a connection device on the printed wiring board;
wherein the connection device comprises:
a main body;
a casing enclosing the main body;
a holder inside the casing configured to hold a connector; and
a terminal extending through the main body and configured to be electrically connected to the connector in the holder,
the main body comprises a first portion extending into the holder in such a manner as to protect a tip of the terminal, and a second portion arranged in a position corresponding to a proximal portion formed at an opposite end of the terminal with respect to the tip and fixed to the casing, and
the first portion is formed independently of the second portion.

2. The printed circuit board of claim 1, wherein the first portion is supported by the terminal.

3. The printed circuit board of claim 2, wherein:
the first portion with a flat structure comprises an end portion opposing the second portion, a first surface opposing a terminal of the connector, and a second surface on an opposite side to the first surface of the first portion, and
the end portion has a semiround cross-section arching toward the second portion on a plane in a thickness direction of the first portion.

4. The printed circuit board of claim 2, wherein:
the first portion with a flat structure comprises an end surface opposing the second portion, a first surface opposing a terminal of the connector, a second surface on the other side of the first portion with respect to the first surface, a first chamfered portion prepared by chamfering a line of intersection between the end surface and the first surface, and a second chamfered portion prepared by chamfering a line of intersection between the end surface and the second surface.

5. An electronic device comprising:
a housing; and
a printed circuit board in the housing;
wherein the printed circuit board comprises:
a printed wiring board; and
a connection device on the printed wiring board,
the connection device comprises:
a main body;
a casing enclosing the main body;
a holder inside the casing configured to hold a connector; and
a terminal extending through the main body and configured to be electrically connected to the connector in the holder,
the main body comprises a first portion extending into the holder in such a manner as to protect a tip of the terminal and a second portion arranged in a position corresponding to a proximal portion formed at an opposite end of the terminal with respect to the tip and fixed to the casing, and
the first portion is formed independently of the second portion.

6. The electronic device of claim 5, wherein the first portion is supported by the terminal.

7. The electronic device of claim 6, wherein:
the first portion with a flat structure comprises an end portion opposing the second portion, a first surface opposing a terminal of the connector, and a second surface on an opposite side to the first surface of the first portion, and
the end portion has a semiround cross-section arching toward the second portion on a plane in a thickness direction of the first portion.

8. The electronic device of claim 6, wherein:
the first portion with a flat structure comprises an end surface opposing the second portion, a first surface opposing a terminal of the connector, a second surface on the other side of the first portion with respect to the first surface, a first chamfered portion prepared by chamfering a line of intersection between the end surface and the first surface, and a second chamfered portion prepared by chamfering a line of intersection between the end surface and the second surface.

9. A connection device comprising:
a main body;
a casing enclosing the main body;
a holder inside the casing configured to hold a connector; and
a terminal extending through the main body and configured to be electrically connected to the connector in the holder,
wherein:
the main body comprises a first portion extending into the holder in such a manner as to protect a tip of the terminal and a second portion arranged in a position corresponding to a proximal portion formed at an opposite end of the terminal with respect to the tip and fixed to the casing, and
the first portion is formed independently of the second portion.

10. The connection device of claim 9, wherein the first portion is supported by the terminal.

11. The connection device of claim 10, wherein:
the first portion with a flat structure comprises an end portion opposing the second portion, a first surface opposing a terminal of the connector, and a second surface on an opposite side to the first surface of the first portion, and
the end portion has a semiround cross-section arching toward the second portion on a plane a thickness direction of the first portion.

12. The connection device of claim 10, wherein:
the first portion with a flat structure comprises an end surface opposing the second portion, a first surface opposing a terminal of the connector, a second surface on the other side of the first portion with respect to the first surface, a first chamfered portion prepared by chamfering a line of intersection between the end surface and the first surface, and a second chamfered portion prepared by chamfering a line of intersection between the end surface and the second surface.
